(19) United States
(12) Patent Application Publication
(10) Pub. No.: US 2025/0048760 A1
(43) Pub. Date: Feb. 6, 2025

(54) ELECTRONIC DEVICE

(71) Applicant: Advanced Semiconductor Engineering, Inc., Kaohsiung (TW)

(72) Inventors: Hsin-Ying HO, Kaohsiung (TW); Lu-Ming LAI, Kaohsiung (TW); Shih-Chieh TANG, Kaohsiung (TW)

(73) Assignee: Advanced Semiconductor Engineering, Inc., Kaohsiung (TW)

(21) Appl. No.: 18/230,579

(22) Filed: Aug. 4, 2023

(51) Int. Cl. H01L 27/146

(52) U.S. Cl. CPC H01L 27/14618; H01L 27/14636

(57) ABSTRACT

An electronic device includes an encapsulant, an optical emitter, and an optical sensor. The optical sensor is encapsulated by the encapsulant. The optical emitter is supported by the encapsulant.

### BACKGROUND

### 1. Field of the Disclosure

The present disclosure relates to an electronic device.

### 2. Description of Related Art

An electronic device that includes an optical emitter and an optical sensor can be used for detecting the presence (or the bioinformation) of an object near the electronic device. The optical sensor receives or senses light emitted from the optical emitter and/or reflected by an object, thereby detecting the presence (or the bioinformation) of the object.

A conventional optical emitter, with a thickness greater than 150 μm, is utilized in various electronic devices. When the optical emitter has a relatively greater thickness (e.g., a thickness greater than 150 μm), light emitted from a lateral surface of the optical emitter occupies greater ratio in comparison with a thinner one, leading to a greater size of an electronic device and a poor efficiency of light output. Conversely, an optical emitter with a small size can facilitate the creation of a smaller electronic device with a more efficient light output. However, integrating a smaller optical emitter and other components, such as an optical sensor and/or an encapsulant, poses a significant challenge in manufacturing processes.

### SUMMARY

According to some embodiments of the present disclosure, an electronic device includes an encapsulant, an optical emitter, and an optical sensor. The optical sensor is encapsulated by the encapsulant. The optical emitter is supported by the encapsulant.

According to some embodiments of the present disclosure, an electronic device includes a first die and a second die. The first die has a first electrical transmission surface and a first optical transmission surface. The second die has a second electrical transmission surface and a second optical transmission surface. A vertical distance between the first optical transmission surface and the second optical transmission surface is less than a vertical distance between the first electrical transmission surface and the second electrical transmission surface.

According to some embodiments of the present disclosure, an electronic device includes a first die, a second die, a carrier, and an interconnection structure. The first die and the second die are disposed on the carrier. The interconnection structure is disposed between and electrically connects the second die and the carrier. A height of an upper surface of the interconnection structure with respect to the carrier is substantially equal to a height of an upper surface of the first die with respect to the carrier.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1A is a cross-sectional view of an electronic device in accordance with some embodiments of the present disclosure.

FIG. 1B is a partial enlarged view of the electronic device of FIG. 1A in accordance with some embodiments of the present disclosure.

FIG. 1C illustrates the relationship between light output and the thickness of an optical emitter in accordance with some embodiments of the present disclosure.

FIG. 2 is a cross-sectional view of an electronic device in accordance with some embodiments of the present disclosure.

FIG. 3 is a cross-sectional view of an electronic device in accordance with some embodiments of the present disclosure.

FIG. 4A is a top view of an electronic device in accordance with some embodiments of the present disclosure.

FIG. 4B is a cross-sectional view of an electronic device in accordance with some embodiments of the present disclosure.

FIG. 5 is a cross-sectional view of an electronic device in accordance with some embodiments of the present disclosure.

FIG. 6A, FIG. 6B-1, FIG. 6B-2, FIG. 6C, FIG. 6D, FIG. 6E, FIG. 6F and FIG. 6G illustrate various stages of a method for manufacturing an electronic device in accordance with some embodiments of the present disclosure.

FIG. 7A, FIG. 7B, FIG. 7C, FIG. 7D, FIG. 7E, and FIG. 7F illustrate various stages of a method for manufacturing an electronic device in accordance with some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

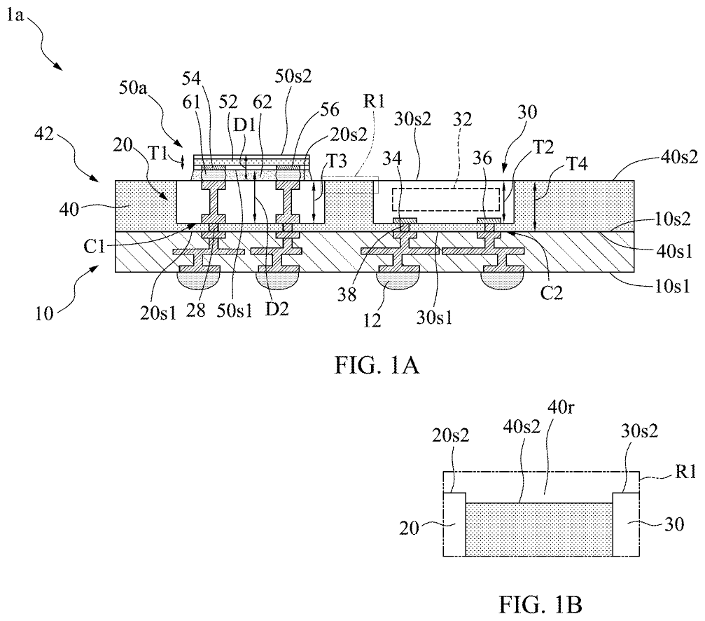

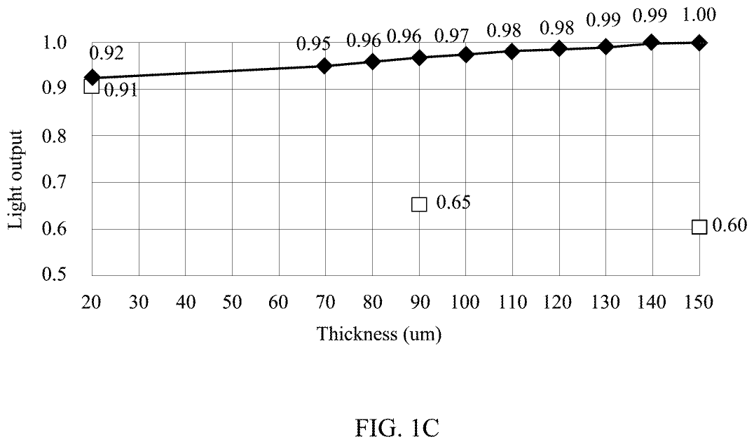

FIG. 1A is a cross-sectional view of an electronic device 1a in accordance with some embodiments of the present disclosure. In some embodiments, the electronic device 1a may include a circuit layer 10, an interposer 20, an optical sensor 30, an encapsulant 40, and an optical emitter 50a.

The circuit layer 10 (or a carrier) may be formed of, for example, a printed circuit board, such as a paper-based copper foil laminate, a composite copper foil laminate, or a polymer-impregnated glass-fiber-based copper foil laminate. The circuit layer 10 may include a redistribution structure or traces, for electrical connection between components. In some embodiments, the circuit layer 10 can be replaced by other suitable carriers, such as a lead frame. The circuit layer 10 may have a surface 10s1 (or a lower surface) and a surface 10s2 (or an upper surface) opposite to the surface 10s1.

The electronic device 1a may include electrical connectors 12. The electrical connector 12 may be disposed on or under the surface 10s1 of the circuit layer 10. The electrical connector 12 may be configured to electrically connect the electronic device 1a and an external device (not shown), such as a circuit board or other suitable devices.

In some embodiments, the interposer 20 (or interconnection structure) may be disposed on or over the surface 10s2 of the circuit layer 10. In some embodiments, the interposer 20 may be configured to support the optical emitter 50a. In some embodiments, the interposer 20 may be configured to electrically connect the optical emitter 50a and the circuit layer 10. The interposer 20 may provide the optical emitter 50a with an electrical path from one side to the opposite side of the encapsulant 40. In some embodiments, the interposer 20 may be vertically disposed between the circuit layer 10 and the optical emitter 50a. The interposer 20 may include an interconnection structure, such as a redistribution structure or other suitable conductive elements. In some embodiments, the interposer 20 may include a core substrate (not annotated) encapsulating the redistribution structure. The core substrate may include prepreg (PP), Ajinomoto build-up film (ABF) or other suitable materials. In some embodiments, a resin material used in the core substrate may be a fiber-reinforced resin so as to strengthen the core substrate, and the reinforcing fibers may be, without limitation to, glass fibers or Kevlar fibers (aramid fibers). The interposer 20 may have a surface 20s1 (or a lower surface) and a surface 20s2 (or an upper surface) opposite to the surface 20s1.

The interposer 20 may include conductive elements 28. The conductive element 28 may be disposed on or under the surface 20s1 of the interposer 20. The conductive element 28 may include, a conductive pillar (e.g., a copper pillar) or other suitable elements.

In some embodiments, the optical sensor 30 (or a die or an electronic component) may be disposed on or over the surface 10s2 of the circuit layer 10. In some embodiments, the optical sensor 30 may be configured to receive a light (or an optical signal) reflected from an object (not shown). In some embodiments, the optical sensor 30 may be disposed adjacent to the interposer 20. In some embodiments, the interposer 20 and the optical sensor 30 may be arranged side by side. In some embodiments, the optical sensor 30 may be spaced apart from the interposer 20 by the encapsulant 40. The optical sensor 30 may be configured to convert an optical signal(s) to an electrical signal(s). The optical sensor 30 may include a photodiode or other suitable element(s). The optical sensor 30 may have a surface 30s1 (or a lower surface or an electrical transmission surface) and a surface 30s2 (or an upper surface or an optical transmission surface) opposite to the surface 30s1. In some embodiments, the surface 30s2 of the optical sensor 30 may be substantially aligned with the surface 20s2 of the interposer 20.

In some embodiments, the optical sensor 30 may include a light-sensing region 32, which is configured to receive a light (or an optical signal). The light-sensing region 32 may be disposed adjacent to the surface 30s1 or surface 30s2. In some embodiments, the light-sensing region 32 may be exposed by the surface 30s2 of the optical sensor 30.

In some embodiments, the optical sensor 30 may include an electrode 34 and an electrode 36. In some embodiments, each of the electrodes 34 and 36 may be configured to receive and/or transmit an input/output signal(s). In some embodiments, the electrodes 34 and 36 may be disposed at the same side of the optical sensor 30. For example, the electrode 34 may be disposed on or embedded adjacent to the surface 30s1 of the optical sensor 30; the electrode 36 may be disposed on or embedded adjacent to the surface 30s1 of the optical sensor 30. Each of the electrodes 34 and 36 may be exposed by the surface 30s1 of the optical sensor 30.

The optical sensor 30 may include conductive elements 38. The conductive element 38 may be disposed on or under the surface 30s1 of the optical sensor 30. The lower surface of the conductive element 38 may be substantially aligned or coplanar with the lower surface of the conductive element 28. The conductive pillars may be electrically connected to the electrodes 24 and 26. The conductive element 38 may include, a conductive pillar (e.g., a copper pillar) or other suitable elements.

In some embodiments, the encapsulant 40 (or a block structure) may be disposed on or over the surface 10s2 of the circuit layer 10. In some embodiments, the encapsulant 40 may encapsulate the interposer 20. In some embodiments, the encapsulant 40 may encapsulate the optical sensor 30. In some embodiments, the encapsulant 40 may encapsulate the conductive elements 28 and 38. In some embodiments, the encapsulant 40 may include a Novolac-based resin, an epoxy-based resin, a silicone-based resin, or another suitable material. Suitable fillers may also be included, such as powdered SiO₂. In some embodiments, the encapsulant 40 may include an opaque material. In some embodiments, the encapsulant 40 may have a transmittance less than 10%, such as 10%, 5%, 3%, 1%, or less, to a peak wavelength of the light emitted by the optical emitter 50a. The encapsulant 40 may have a surface 40s1 (or a lower surface) and a surface 40s2 (or an upper surface) opposite to the surface 40s1. In some embodiments, the interposer 20 and the encapsulant 40 may collectively define a package structure 42. The surface roughness of the surface 40s1 may be different from that of the surface 40s2.

In some embodiments, the exposed portion of the optical sensor 30 (e.g., surface 30s2), which is exposed by the encapsulant 40, and the exposed portion of the optical emitter 50a, which is exposed by the encapsulant 40, are at different elevation levels. In some embodiments, the exposed portion of the optical emitter 50a, which is exposed by the encapsulant 40, and the surface 40s1 of the encapsulant 40 are at different elevation levels.

In some embodiments, the optical emitter 50a (or a die or an electronic component) may be disposed on or over the surface 20s2 of the interposer 20. In some embodiments, the optical emitter 50a may be bonded to the interposer 20 by a flip-chip technique. In some embodiments, the optical emitter 50a may be electrically connected to the circuit layer 10 through the interposer 20. In some embodiments, the optical emitter 50a may be spaced apart from the circuit layer 10 by the interposer 20. The optical emitter 50a may be supported by the interposer 20 (or encapsulant 40). In some embodiments, the optical emitter 50a may be configured to emit light toward an object (not shown). In some embodiments, the optical emitter 50a may include a light-emitting diode (LED), such as a micro LED, mini LED, quantum dot (LED) or other suitable devices. In other embodiments, the optical emitter 50a may include an organic light-emitting diode (OLED). In some embodiments, the optical emitter 50a may be free from vertically overlapping the optical sensor 30. In some embodiments, the optical emitter 50a may be free from laterally overlapping the optical sensor 30. In some embodiments, the optical emitter 50a may be spaced apart from the encapsulant 40. In some embodiments, the optical emitter 50a may be free from vertically overlapping the encapsulant 40. In some embodiments, the optical emitter 50a may be free from laterally overlapping the encapsulant 40. The optical emitter 50a may have a surface 50s1 (a lower surface or an electrical transmission surface) and a surface 50s2 (or an upper surface or an optical transmission surface) opposite to the surface 50s1. In some embodiments, the roughness of the surface 50s2 may be different from that of the surface 50s1. In some embodiments, the roughness of the surface 50s2 may be greater than that of the surface 50s1. In some embodiments, the optical emitter 50a may have a dimension (e.g., surface area, volume, thickness or the like) smaller than that of the interposer 20. In some embodiments, the optical emitter 50a may have a weight less than that of the interposer 20. A distance (or vertical distance) D1 between the surfaces 30s2 and surface 50s2 is less than a distance D2 between the surfaces 30s1 and 50s1.

The optical emitter 50a may include a light-emitting layer 52, an electrode 54, and an electrode 56. The light-emitting layer 52 may be disposed adjacent to the surface 50s1 and/or surface 50s2. The light-emitting layer 52 may be configured to emit a light (or an optical signal), such as a light with a wavelength from about 400 nm to about 500 nm (e.g., blue light), a light with a wavelength from about 500 nm to about 580 nm (e.g., green light), a light with a wavelength from about 620 nm to about 780 nm (e.g., red light), a light with a wavelength from about 780 nm to about 3000 nm (e.g., infrared), a light with a wavelength from about 100 nm to about 390 nm (e.g., ultraviolet). Although not shown, the optical emitter 50a may include other layers, such as a hole transportation layer (HTL), electron transportation layer (ETL), carrier injection layer, or other suitable layers.

In some embodiments, each of the electrodes 54 and 56 may be configured to receive and/or transmit an input/output signal(s). In some embodiments, the electrodes 54 and 56 may be disposed at the same side of the optical emitter 50a. For example, the electrode 54 may be disposed on or embedded adjacent to the surface 50s1 of the optical emitter 50a; the electrode 56 may be disposed on or embedded adjacent to the surface 50s1 of the optical emitter 50a. Each of the electrodes 54 and 56 may be exposed by the surface 50s1 of the optical emitter 50a.

The optical emitter 50a may have a thickness T1. In some embodiments, the thickness T1 may range from about 1 μm to about 150 μm, such as 1 μm, 10 μm, 20 μm, 30 μm, 40 μm, 50 μm, 60 μm, 70 μm, 80 μm, 90 μm, 100 μm, 110 μm, 120 μm, 130 μm, 140 μm, or 150 μm. In some embodiments, the thickness T1 may range from about 10 μm to about 90 μm. In some embodiments, the optical emitter 50a may have a substantial square (or rectangular) profile, and the length (or width) of the optical emitter 50a may be less than 700 μm, 600 μm, 500 μm, 400 μm, 300 μm, or less.

The optical sensor 30 may have a thickness T2. The interposer 20 may have a thickness T3. The encapsulant 40 may have a thickness T4. In some embodiments, the thickness T2 may be substantially the same as the thickness T3. In some embodiments, the thickness T2 may be less than the thickness T4. In some embodiments, the thickness T3 may be less than the thickness T4. In some embodiments, the thickness T2 may be greater than the thickness T1.

In some embodiments, the electronic device 1a may include electrical connectors 61. The electrical connector 61 may be disposed between the optical emitter 50a and the interposer 20. The electrical connector 61 may be connected to the electrodes 54 and 56. The electrical connector 61 may include a solder element, conductive bump, or the like. The electrical connector 61 may include alloys of gold and tin solder or alloys of silver and tin solder, or other suitable materials.

In some embodiments, the electronic device 1a may include a protective layer 62. The protective layer 62 may be disposed between the optical emitter 50a and the interposer 20. The protective layer 62 may encapsulate the electrical connectors 61. In some embodiments, the protective layer 62 may be in contact with the surface 20s2 of the interposer 20. In some embodiments, the protective layer 62 may be spaced apart from the encapsulant 40. The protective layer 62 may include a resin or other suitable material(s).

A conductive structure C1, which includes the traces within the interposer 20 and the conductive element 28, and a conductive structure C2, which includes the conductive element 38, may have different lengths (or vertical lengths).

FIG. 1B is a partial enlarged view of region R1 of the electronic device of FIG. 1A in accordance with some embodiments of the present disclosure. The surface 40s2 of the encapsulant 40 may have an elevation (or height or elevation level) less than that of the surface 20s2 of the interposer 20. The surface 40s2 of the encapsulant 40 may have an elevation (or height or elevation level) less than that of the surface 30s2 of the optical sensor 30. The encapsulant may define a recess 40r between the interposer 20 and the optical sensor 30.

FIG. 1C illustrates the relationship between light output and the thickness of an optical emitter in accordance with some embodiments of the present disclosure.

The longitudinal axis of the chart indicates the amount (or intensity) of the light output of an optical emitter, wherein the amount (or intensity) of the light output of an optical emitter with a thickness of 150 μm is defined as 1; the horizontal axis of the chart indicates the thickness of an optical emitter. The rhombus point indicates the total light output of an optical emitter, which includes the light emitted from a lateral surface and from an upper surface of an optical emitter. The square point indicates the light output which includes the light from only an upper surface of an optical emitter. The light emitted from the lateral surface of an optical emitter may be incident to a target object through one or more reflections, leading to a longer transmission path. As a result, less light may be incident to and then received by an optical sensor. Conversely, the light emitted from the upper surface of an optical emitter may be incident to a target object without being reflected, leading to more lights received by an optical sensor.

As shown in FIG. 1C, as the thickness of an optical emitter decreases, the total light output decreases slightly. For example, when an optical emitter has a thickness of 20 μm, the total light output is 0.92, which is 8% less than the total light output of an optical emitter with a thickness of 150 μm. However, when the thickness of an optical emitter decreases, the light output from the upper surface increases. For example, when an optical emitter has a thickness of 150 μm, the light output from the upper surface of an optical emitter occupies only 60% of the total light output. That is, the light output from the lateral surface of an optical emitter occupies 40% of the total light output, which is received by an optical sensor less effectively. When an optical emitter has a thickness of 90 μm, the light output from the upper surface of an optical emitter is 0.65, which is 5% more than the light output of an optical emitter with a thickness of 150 μm. When an optical emitter has a thickness of 20 μm, the light output from the upper surface of an optical emitter is 0.91, which is 31% more than the light output of an optical emitter with a thickness of 150 μm. Therefore, even though the total light output of an optical emitter with a thickness of 20 μm is slightly less than that of an optical emitter with a thickness of 150 μm, the light output from the upper surface of an optical emitter with a thickness of 20 μm is much greater than that of an optical emitter with a thickness of 150 μm. In conclusion, when an optical emitter has a smaller dimension, the total size of an electronic device may be reduced. Further, an optical sensor can receive the light emitted from a smaller optical emitter more effectively.

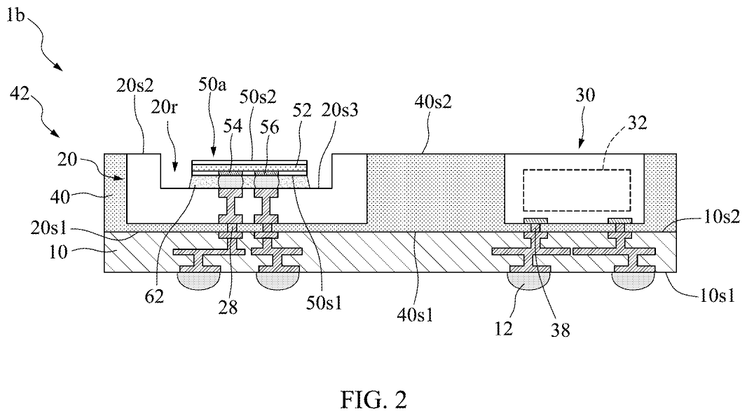

FIG. 2 is a cross-sectional view of an electronic device 1b in accordance with some embodiments of the present disclosure. The electronic device 1b has a structure similar to that of the electronic device 1a with differences described below.

In some embodiments, the interposer 20 may define a recess 20r recessed from the surface 20s2. The interposer 20 may have a surface 20s3 (or an upper surface) recessed from the surface 20s2. The surface 20s3 may function as a bottom of the recess 20r.

In some embodiments, the optical emitter 50a may be disposed on or over the surface 20s3 of the interposer 20. In some embodiments, the optical emitter 50a may laterally overlap the encapsulant 40. In some embodiments, the optical emitter 50a may laterally overlap the optical sensor 30. In some embodiments, the optical emitter 50a may be spaced apart from the optical sensor 30 by the interposer 20. In some embodiments, the optical emitter 50a may be spaced apart from the optical sensor 30 by the encapsulant 40. In some embodiments, the surface 50s2 of the optical emitter 50a may be located at an elevation (or elevation level) with respect to the circuit layer 10 less than (or equal to) the elevation (or elevation level) of the surface 20s2 of the interposer 20 with respect to the circuit layer 10.

In some embodiments, the light-emitting layer 52 may be located at an elevation (or elevation level) between that of the surface 20s2 of the interposer 20 and that of the electrode 54 (or electrode 56). In some embodiments, the light-emitting layer 52 may be located at an elevation (or elevation level) between that of the surface 20s3 of the interposer 20 and that of the surface 20s2 of the interposer 20. The light-emitting layer 52 may be located at an elevation (or elevation level) adjacent to the surface 40s2 of the encapsulant 40.

In some embodiments, the protective layer 62 may be in contact with the surface 20s3 of the interposer 20.

In this embodiment, the optical emitter 50a may be accommodated within the recess 20r of the interposer 20, leading to a smaller size (e.g., thickness) of the electronic device 1b.

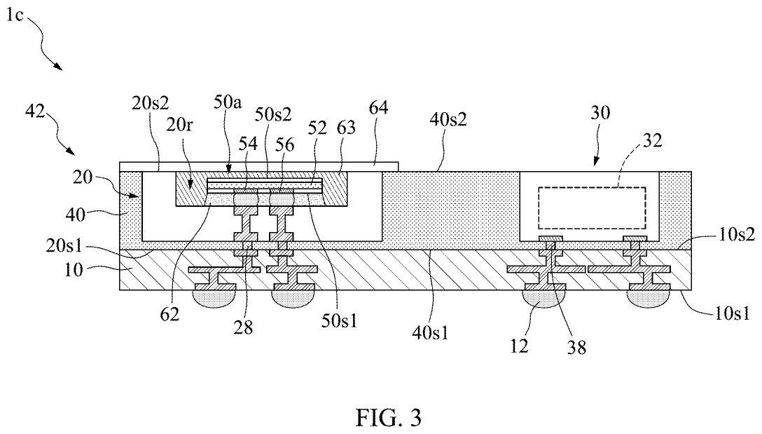

FIG. 3 is a cross-sectional view of an electronic device 1c in accordance with some embodiments of the present disclosure. The electronic device 1c has a structure similar to that of the electronic device 1b with differences described below.

In some embodiments, the electronic device 1c may include a filler 63. In some embodiments, the filler 63 may fill the recess 20r of the interposer 20. The filler 63 may encapsulate the optical emitter 50a. In some embodiments, the filler 63 may include a transparent material. For example, the filler 63 is transparent to a peak wavelength of light emitted by the optical emitter 50a. In some embodiments, the filler 63 may have a transmittance exceeding 90% to a peak wavelength of the light emitted by the optical emitter 50a; the filler 63 may have a transmittance exceeding 95% to a peak wavelength of the light emitted by the optical emitter 50a; and the filler 63 may have a transmittance exceeding 98% to a peak wavelength of the light emitted by the optical emitter 50a.

In some embodiments, the electronic device 1c may include an anti-reflection layer 64. The anti-reflection layer 64 may be disposed on or over the surface 50s2 of the optical emitter 50a. The anti-reflection layer 64 may be disposed on or over the surface 20s2 of the interposer 20. In some embodiments, the anti-reflection layer 64 may vertically overlap the interposer 20. The anti-reflection layer 64 may be disposed on or over the surface 40s2 of the encapsulant 40. In some embodiments, the anti-reflection layer 64 may vertically overlap the encapsulant 40. The anti-reflection layer 64 may be configured to improve the efficiency of light output of the optical emitter 50a. In other embodiments, the anti-reflection layer 64 may be embedded with the filler 63, and an upper surface of the anti-reflection layer 64 may be substantially aligned with the surface 20s2 of the interposer.

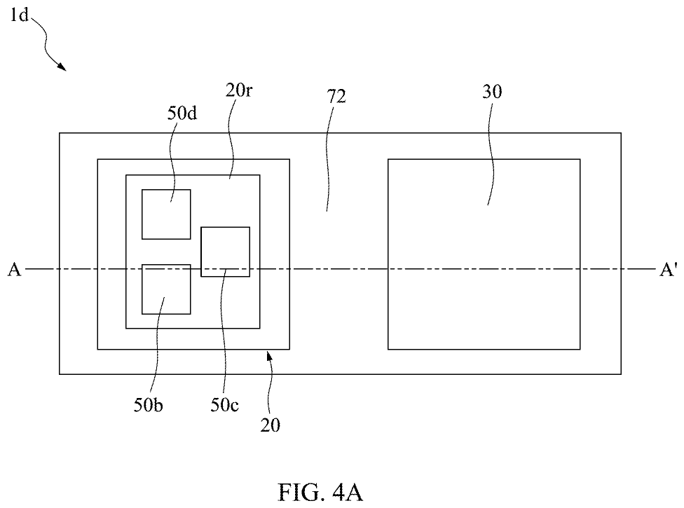

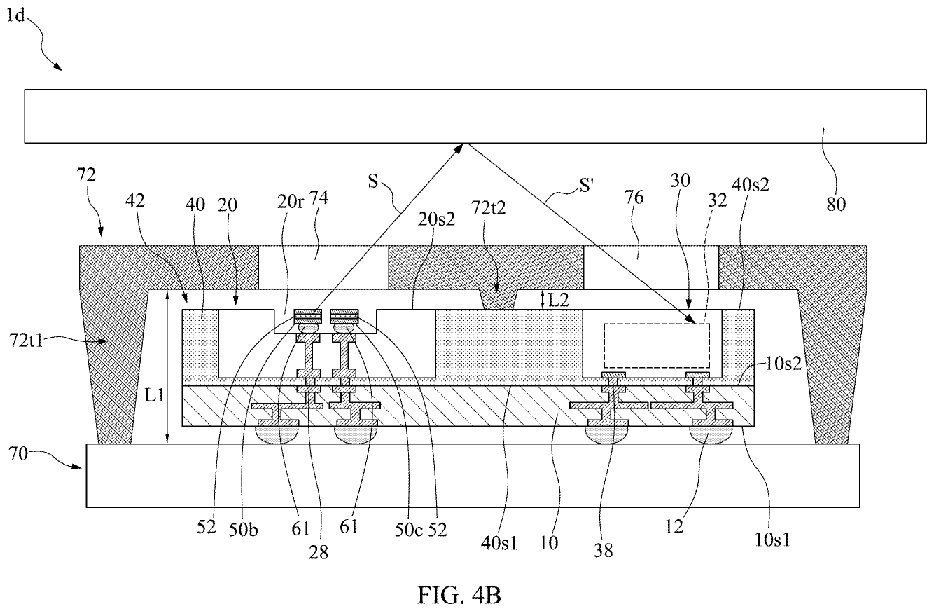

FIG. 4A and FIG. 4B illustrate an electronic device 1d in accordance with some embodiments of the present disclosure, wherein FIG. 4A is a top view, and FIG. 4B is a cross-sectional view along line A-A′ of FIG. 4A.

Referring to FIG. 4A, the electronic device 1d may include two or more optical emitters. For example, the electronic device 1d may include optical emitters 50b, 50c, and 50d. The optical emitters 50b, 50c, and 50d may be located within the recess 20r of the interposer 20. In some embodiments, the optical emitters 50b, 50c, and 50d may be configured to emit light with different wavelengths.

Referring to FIG. 4B, the electronic device 1d may include a circuit structure 70 and a light block layer 72. The circuit structure 70 may support the light block layer 72. The circuit structure 70 may support and be electrically connected to the circuit layer 10. The circuit structure 70 may be formed of, for example, a printed circuit board, such as a paper-based copper foil laminate, a composite copper foil laminate, or a polymer-impregnated glass-fiber-based copper foil laminate. The circuit structure 70 may include a redistribution structure or traces, for electrical connection between components.

In some embodiments, the light block layer 72 may be disposed over the circuit structure 70. The light block layer 72 may cover the package structure 42. The light block layer 72 may be configured to block the light in communication between the optical emitter 50b (or 50c or 50d) and the optical sensor 30 with an undesired angle. The circuit structure 70 may include an opaque material. In some embodiments, the circuit structure 70 may have a transmittance less than 10%, such as 10%, 5%, 3%, 1%, or less, to a peak wavelength of the light emitted by the optical emitter 50b (or 50c or 50d). The light block layer 72 may include a black photoresist, black ink, black polymer or other suitable materials.

The light block layer 72 may have a portion 72t1 and a portion 72t2. The portion 72t1 may be connected to the circuit structure 70 and have a length L1. The portion 72t2 may be connected to the package structure 42 (or encapsulant 40) and have a length L2. In some embodiments, the length L1 may be greater than the length L2.

Although FIG. 4B illustrates that the light block layer 72 is disposed over the circuit structure 70, the light block layer 72 may be connected to another opaque material and function as an frame of the electronic device 1d. In this embodiment, the circuit structure 70 may be enclosed by said frame including the light block layer 72.

The light block layer 72 may define an optically transparent region 74 and an optically transparent region 76. The optically transparent region 74 may be located directly over the optical emitter 50a. In some embodiments, the optically transparent region 74 may include a transparent material (e.g., glass, resin, or the like) or air. The optically transparent region 76 may be located directly over the optical sensor 30. In some embodiments, the optically transparent region 76 may include a transparent material (e.g., glass, resin, or the like) or air.

As shown in FIG. 4B, the optical emitter 50b (or 50c or 50d) may emit a light S. The light S may be incident to an object 80 through the optically transparent region 74. The light-sensing region 32 of the optical sensor 30 may receive a reflected light S′ from the object 80 through the optically transparent region 76. The information of the light S′ (e.g., power, wavelength, or the like) may be different from that of the light S, and the information (e.g., bioinformation) of the object 80 can be acquired by comparing the lights S and S′.

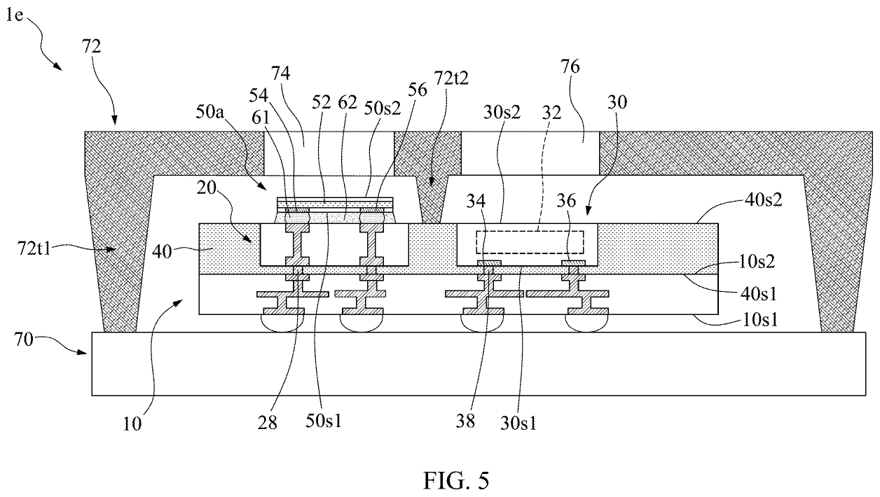

FIG. 5 is a cross-sectional view of an electronic device 1e in accordance with some embodiments of the present disclosure. The electronic device 1e has a structure similar to that of the electronic device 1d with differences described below.

In some embodiments, the optical emitter 50a may be disposed on or over the interposer 20. In some embodiments, the optical emitter 50a may laterally overlap the portions 72t1 and 72t2 of the light block layer 72.

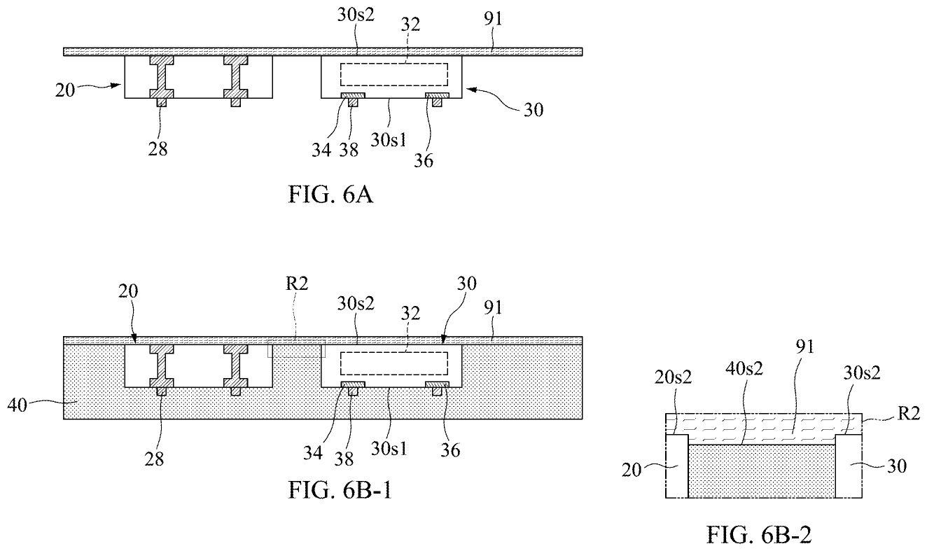

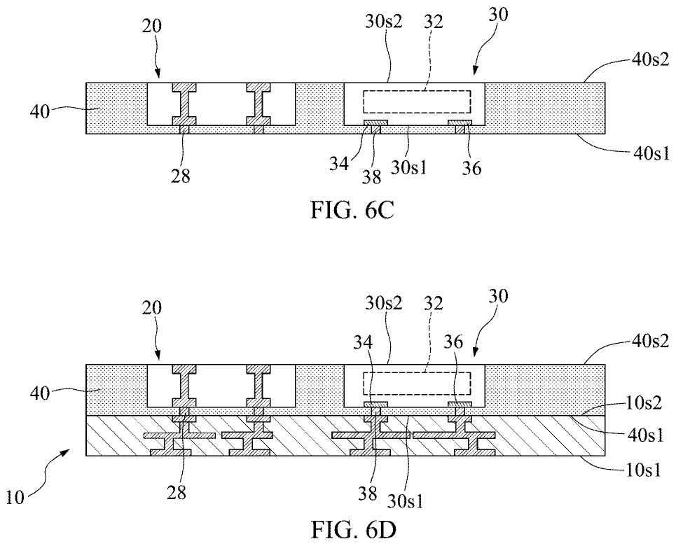

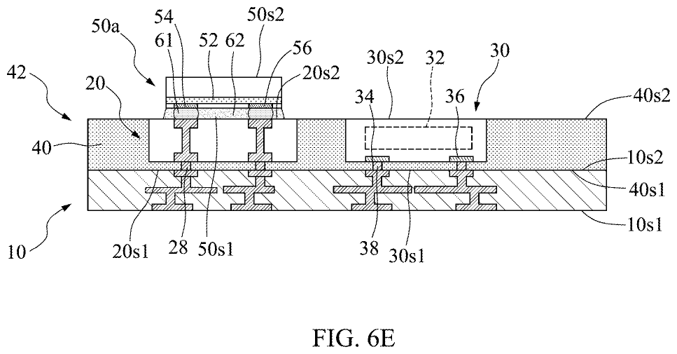

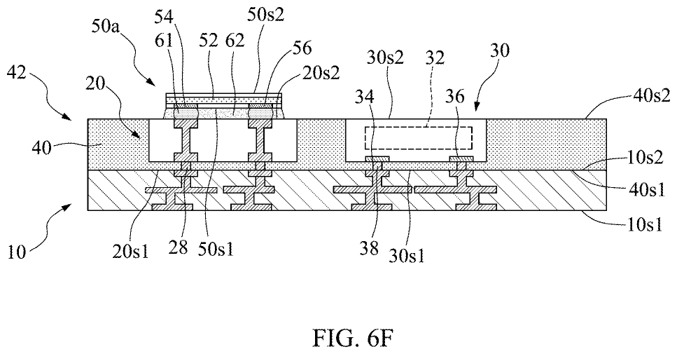

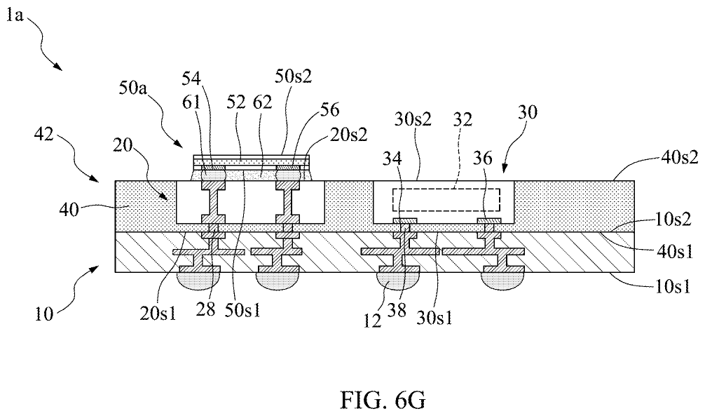

FIG. 6A, FIG. 6B-1, FIG. 6B-2, FIG. 6C, FIG. 6D, FIG. 6E, FIG. 6F and FIG. 6G illustrate various stages of a method for manufacturing an electronic device in accordance with some embodiments of the present disclosure.

Referring to FIG. 6A, an interposer 20 and an optical sensor 30 may be received or provided. The interposer 20 and the optical sensor 30 may be attached to a carrier 91 by a pick-and-place technique. For example, a vacuum nozzle (not shown) may be used to suction the interposer 20 (or optical sensor 30) and release the interposer 20 (or optical sensor 30) on the carrier 91. In some embodiments, the carrier 91 may include a tape or other suitable components. The optical sensor 30 may have an electrode 34 and an electrode 36 (or input/output (I/O) terminals) located at a surface (e.g., surface 30s1) spaced apart from the carrier 91. Since an optical film (e.g., an anti-reflection coating, not shown) may be coated on the surface 30s2 (or backside surface), which is configured for receiving light, the surface 30s2 cannot be ground. Further, conductive elements 38 are disposed on or under the electrodes 34 and 36, which can prevent from electrodes 34 and 36 being etched in subsequent stages (e.g., a polishing or grinding stage). Therefore, the surface 30s1 is located a side far away from the carrier 91. Similarly, conductive elements 28 can prevent from the terminals of the interposer being etched in subsequent stages (e.g., a polishing or grinding stage).

Referring to FIG. 6B-1, an encapsulant 40 may be formed on the carrier 91 to encapsulate the interposer 20 and the optical sensor 30. The encapsulant 40 may be formed by a molding technique, such as an injection molding, blow molding, compression molding, extrusion molding, or other suitable techniques.

Referring to FIG. 6B-2, which is a partial enlarged view of region R2 of FIG. 6B-1, the optical sensor 30 may be partially inserted into the carrier 91, and the interposer 20 may be partially inserted into the carrier 91. As a result, a protrusion 91p of the carrier 91 may be formed between the interposer 20 and the optical sensor 30.

Referring to FIG. 6C, the encapsulant 40 may be ground or polished until the conductive elements 28 and 38 are exposed. The carrier 91 may be removed. The surface 40s1, which is ground, and the surface 40s2 may have different surface roughness. The surface 40s1 has a greater surface roughness than that of the surface 40s2.

Referring to FIG. 6D, a circuit layer 10 may be formed on the interposer 20 and the optical sensor 30.

Referring to FIG. 6E, an optical emitter 50a may be attached to the interposer 20. The optical emitter 50a may be attached to the interposer 20a by a flip-chip technique. The optical emitter 50a may be attached to the interposer 20 by electrical connectors 61. A protective layer 62 may be formed to encapsulate the electrical connectors 61.

Referring to FIG. 6F, the optical emitter 50a may be thinned. In some embodiments, the substrate (e.g., silicon substrate or other suitable substrates) of the optical emitter 50a may be removed so that the light-emitting layer 52 may be adjacent to a surface 50s2 of the optical emitter 50a. In some embodiments, the optical emitter 50a may be thinned by a laser lift-off technique or other suitable techniques.

Referring to FIG. 6G, electrical connectors 12 may be formed on or under the surface 10s1 of the circuit layer 10. As a result, an electronic device (e.g., electronic device 1a as shown in FIG. 1A) may be produced.

Since the size (e.g., volume, surface, and the like) or weight of the optical emitter 50a is reduced, the optical emitter 50a may be washed away during a molding technique, which results in a reduced yield when manufacturing electronic devices. In this embodiment, the interposer 20 replaces the optical emitter 50a to be attached to the carrier 91. When a molding technique is performed, the interposer 20 may be encapsulated without being washed away due to a greater size or weight in comparison with the optical emitter 50a. As a result, the yield of manufacturing the electronic device 1a may be enhanced.

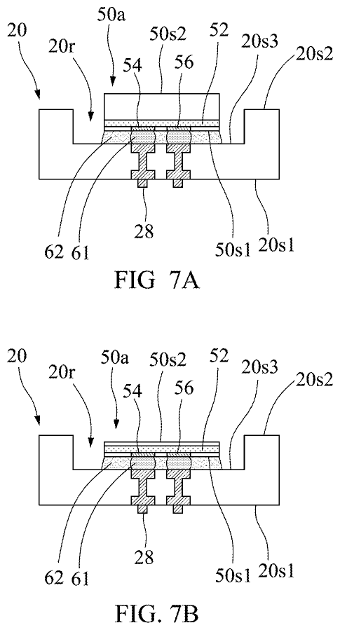

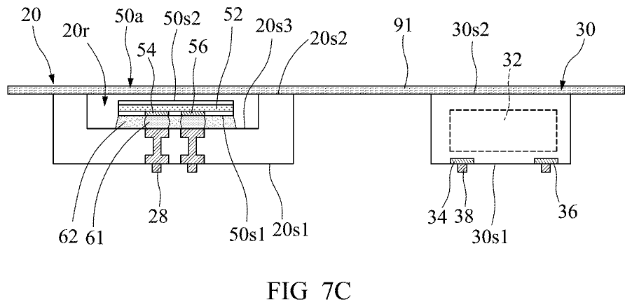

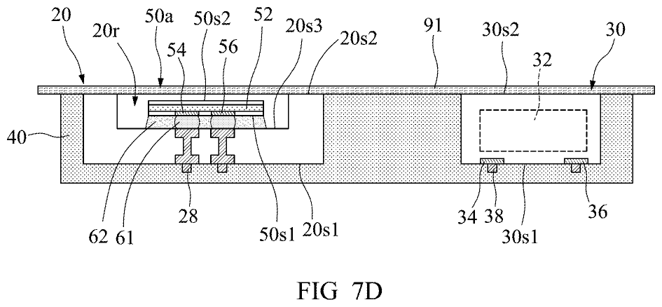

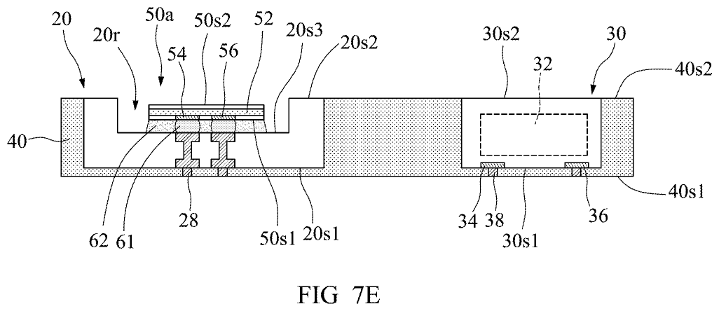

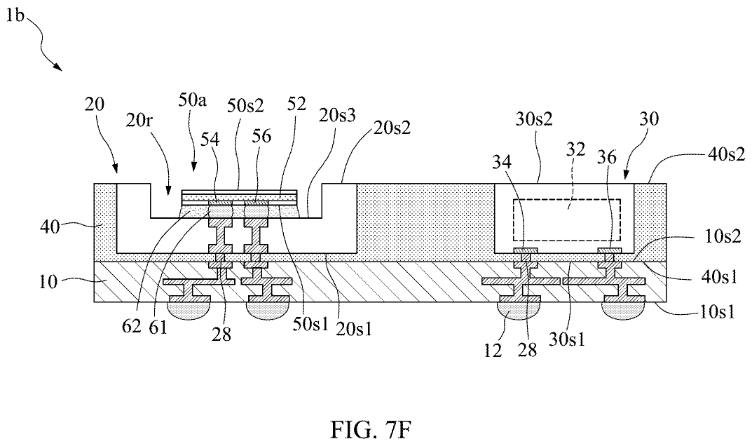

FIG. 7A, FIG. 7B, FIG. 7C, FIG. 7D, FIG. 7E, and FIG. 7F illustrate various stages of a method for manufacturing an electronic device in accordance with some embodiments of the present disclosure.

Referring to FIG. 7A, an interposer 20 and an optical emitter 50a may be provided or received. The optical emitter 50a may be accommodated within the recess 20r of the interposer 20.

Referring to FIG. 7B, the optical emitter 50a may be thinned. In some embodiments, the substrate (e.g., silicon substrate or other suitable substrates) of the optical emitter 50a may be removed so that the light-emitting layer 52 may be adjacent to a surface 50s2 of the optical emitter 50a. In some embodiments, the optical emitter 50a may be thinned by a laser lift-off technique or other suitable techniques. The surface 50s2 of the optical emitter 50a may have an elevation (or an elevation level) less than that of the surface 20s2 with respect to the surface 20s1 of the interposer 20 so that when the interposer 20 is attached to a carrier (e.g., carrier 91 as shown in FIG. 7C), the surface 20s2 may be disposed against the carrier, which thereby forms a recess 20r. As a result, the recess 20r may be free of filling of a molding material (e.g., encapsulant 40 as shown in FIG. 7D) at a stage as shown in FIG. 7D. In other embodiments, a filler (e.g., an optically transparent filler) may fill the recess 20r so that the recess 20r may be free of filling of a molding material.

Referring to FIG. 7C, the interposer 20 and the optical sensor 30 may be attached to a carrier 91. The recess 20r of the interposer 20 may be covered by the carrier 91. In some embodiments, the electrodes 34 and 36 may be located at a surface (e.g., surface 30s1) spaced apart from the carrier 91. The interposer 20 and the optical sensor 30 may be attached to the carrier 91 by a pick-and-place technique.

Referring to FIG. 7D, an encapsulant 40 may be formed on or over the carrier 91 to encapsulate the interposer 20 and the optical sensor 30. The encapsulant 40 may be formed by a molding technique, such as an injection molding, blow molding, compression molding, extrusion molding, or other suitable techniques.

Referring to FIG. 7E, the encapsulant 40 may be ground or polished until the electrodes 34 and 36 are exposed. The terminals (not annotated) of the interposer 20 may be exposed by the encapsulant 40. The carrier 91 may be removed.

Referring to FIG. 7F, a circuit layer 10 may be formed on or under the interposer 20 and the optical sensor 30. The electrical connectors 12 may be formed on or under the surface 10s1 of the circuit layer 10. As a result, an electronic device (e.g., electronic device 1b as shown in FIG. 2) may be produced.

In this embodiment, the optical emitter 50a is embedded within the interposer 20. When a molding technique is performed, the optical emitter 50a may be free from direct contact with a molding material when a molding technique is performed. The interposer 20 may be encapsulated without being washed away due to a greater size or weight in comparison with the optical emitter 50a. As a result, the yield of manufacturing the electronic device 1b may be enhanced.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an encapsulant;
an optical sensor encapsulated by the encapsulant; and
an optical emitter supported by the encapsulant.

2. The electronic device of claim 1, wherein the optical emitter is spaced apart from the encapsulant.

3. The electronic device of claim 2, further comprising:
an interconnection structure configured to provide the optical emitter with an electrical path from a first side of the encapsulant to a second side, opposite to the first side, of the encapsulant.

4. The electronic device of claim 3, wherein the interconnection structure is encapsulated by the encapsulant, and the interconnection structure and the encapsulant collectively support the optical emitter.

5. The electronic device of claim 1, wherein the encapsulant has a first surface exposing the optical emitter and the optical sensor.

6. The electronic device of claim 5, wherein an exposed portion of the optical sensor and an exposed portion of the optical emitter are at different elevation levels.

7. The electronic device of claim 6, wherein the exposed portion of the optical emitter and the first surface of the encapsulant are at different elevation levels.

8. The electronic device of claim 7, wherein the exposed portion of the optical emitter is located between the first surface and a second surface, opposite to the first surface, of the encapsulant.

9. The electronic device of claim 1, wherein the encapsulant has a first surface and a second surface opposite to the first surface, and a surface roughness of the first surface is different from a surface roughness of the second surface.

10. The electronic device of claim 9, wherein the optical sensor has a surface exposed by and higher than the first surface of the encapsulant.

11. An electronic device, comprising:
a first die having a first electrical transmission surface and a first optical transmission surface; and
a second die having a second electrical transmission surface and a second optical transmission surface,
wherein a vertical distance between the first optical transmission surface and the second optical transmission surface is less than a vertical distance between the first electrical transmission surface and the second electrical transmission surface.

12. The electronic device of claim 11, further comprising:
a carrier, wherein both the first electrical transmission surface and the second electrical transmission surface face and are electrically connected to the carrier.

13. The electronic device of claim 12, further comprising:
a first conductive structure electrically connecting the first electrical transmission surface and the carrier; and
a second conductive structure electrically connecting the second electrical transmission surface and the carrier,
wherein a length of the first conductive structure is different from a length of the second conductive structure.

14. The electronic device of claim 11, wherein the first optical transmission surface is located a height substantially equal to that of the second optical transmission surface.

15. The electronic device of claim 11, further comprising:
a block structure encapsulating the first die and exposing the first optical transmission surface.

16. The electronic device of claim 15, wherein the block structure is spaced apart from the second optical transmission surface.

17. The electronic device of claim 16, wherein the block structure laterally overlaps the second die.

18. An electronic device, comprising:
a first die and a second die disposed on a carrier; and
an interconnection structure disposed between and electrically connecting the second die and the carrier,
wherein a height of an upper surface of the interconnection structure with respect to the carrier is substantially equal to a height of an upper surface of the first die with respect to the carrier.

19. The electronic device of claim 18, wherein the interconnection structure has a recess configured to accommodate the second die.

20. The electronic device of claim 19, wherein a height of an upper surface of the second die with respect to the carrier is equal to or less than the height of the upper surface of the interconnection structure with respect to the carrier.
